(19) United States
(12) Patent Application Publication
(10) Pub. No.: US 2014/0004683 A1
(43) Pub. Date: Jan. 2, 2014

(54) METHOD OF MANUFACTURING SEMICONDUCTOR ELEMENT

(71) Applicant: NITTO DENKO CORPORATION, Osaka (JP)

(72) Inventors: Shinya Akizuki, Ibaraki-shi (JP); Toshimasa Sugimura, Ibaraki-shi (JP); Daisuke Uenda, Ibaraki-shi (JP); Takeshi Matsumura, Ibaraki-shi (JP)

(21) Appl. No.: 13/924,420

(22) Filed: Jun. 21, 2013

(30) Foreign Application Priority Data
Jun. 27, 2012 (JP) 2012-144369

(51) Int. Cl. H01L 21/58

(52) U.S. Cl. CPC H01L 21/58
USPC 438/455

(57) ABSTRACT

A method of manufacturing a semiconductor element is provided. The method includes the steps of: bonding a substrate for transferring and a functional layer that is formed on a substrate for forming a functional layer with a temporary fixing layer interposed therebetween; removing the substrate for forming a functional layer to expose the functional layer; bonding a final substrate to the exposed functional layer; and separating the temporary fixing layer and the substrate for transferring from the functional layer, wherein the temporary fixing layer has (A) a specific shear adhering strength or has (B) a specific weight loss rate.

### BACKGROUND OF THE INVENTION

1. Field of the Invention

The present invention relates to a method of manufacturing a semiconductor element.

2. Description of the Related Art

Previously, a method has been known of forming a functional layer on a substrate for forming a functional layer such as GaAs, GaP, sapphire, and SiC with a liquid phase epitaxial growth method or a metal organic chemical vapor deposition method. The functional layer can be used in a photoelectric device, etc. However, the substrate for forming a functional layer generally has low thermal conductivity, and an improvement in heat dissipation characteristics has been demanded.

In recent years, the functional layer has been peeled off from the substrate for forming a functional layer and transferred onto a substrate with high thermal conductivity to improve the heat dissipation characteristics. Previously, as a method (lift-off method) of peeling off a thin functional layer from the substrate for forming a functional layer, methods have been known in which a substrate for transferring is bonded once to a surface opposite to the surface of the substrate for forming a functional layer where the functional layer is disposed, and then the substrate for transferring is peeled off by an YAG laser or Excimer laser (for example, JP-A-2009-76749 and JP-A-2010-87092). A method has been also known in which an etching layer is provided between the functional layer and the substrate for forming a functional layer in advance, and then the etching layer is etched to be peeled off (for example, JP-A-2009-99989).

A method of transferring a functional layer is described below when a previous wet etching is adopted. FIGS. 7 to 11 are cross-sectional schematic views for illustrating a previous method of transferring a substrate.

As shown in FIG. 7, a first etching layer 102 is formed on a substrate 100 for forming a functional layer. Then, a functional layer 104 is formed on the first etching layer 102 with a liquid phase epitaxial growth method or a metal organic chemical vapor deposition method. A second etching layer 106 is formed on the functional layer 104. On the other hand, a substrate 110 for transferring is prepared in which a heat resistant adhesive layer 114 is formed with a third etching layer 112 interposed therebetween.

Then, the heat resistant adhesive layer 114 and the second etching layer 106 are bonded together (see FIG. 8).

The first etching layer 102 is etched using an etchant for etching the first etching layer 102. Thus, the substrate 100 for forming a functional layer is removed, and the functional layer 104 is exposed (see FIG. 9).

Then, a final substrate 120 is bonded to the exposed functional layer 104 (see FIG. 10).

The second etching layer 106 is etched using an etchant for etching the second etching layer 106. Thus, the heat resistant adhesive layer 114 and the substrate 110 for transferring are separated from the functional layer 104 (see FIG. 11).

The functional layer 104 is transferred to the final substrate 120 from the substrate 100 for forming a functional layer.

In a procedure of transferring the functional layer from the substrate for forming a functional layer to the final substrate, the functional layer is first bonded to the substrate for transferring, and then the substrate for forming a functional layer is removed in this state. After that, the final substrate is bonded to the exposed functional layer, and the substrate for transferring is finally separated from the functional layer. In the above-described previous transferring method, the functional layer 104 is bonded to the substrate 110 for transferring with the second etching layer 106 and the heat resistant adhesive layer 114 interposed therebetween, and the substrate 100 for forming a functional layer is removed in this state. After that, the final substrate 120 is bonded to the exposed functional layer 104, and the second etching layer 106 is finally etched to separate the heat resistant adhesive layer 114 and the substrate 110 for transferring from the functional layer 104 (see FIG. 11).

The reason for adopting this procedure is because it is necessary to provide the second and third etching layers due to the fact that it becomes difficult to peel off the heat resistant adhesive layer 114 after an object to be adhered is once adhered.

However, there are a large number of steps in the method of transferring a functional layer using the previous wet etching, and thus a further improvement in production efficiency is demanded.

### SUMMARY OF THE INVENTION

The present invention is made in view of the above-described problems, and its objective is to provide a method of manufacturing a semiconductor element that enables a further improvement in production efficiency.

The present inventors have made investigation to solve the above-described problems. As a result, they have found that a specific temporary fixing layer can be used to improve the production efficiency, and the present invention has been completed.

That is, a method of manufacturing a semiconductor element according to the present invention includes the steps of:
bonding a substrate for transferring and a functional layer that is formed on a substrate for forming a functional layer with a temporary fixing layer interposed therebetween;
removing the substrate for forming a functional layer to expose the functional layer;
bonding a final substrate to the exposed functional layer; and
separating the temporary fixing layer and the substrate for transferring from the functional layer, wherein
the temporary fixing layer has (A) a shear adhering strength to a silicon wafer, after it is kept at 200° C. for 1 minute, of 0.25 kg/5×5 mm or more at the temperature, and a shear adhering strength to a silicon wafer, after it is kept at any temperature range of higher than 200° C. and 500° C. or lower for 3 minutes, of less than 0.25 kg/5×5 mm at the temperature, or has (B) a weight loss rate, after it is immersed in N-methyl-2-pyrrolidone at 50° C. for 60 seconds and dried at 150° C. for 30 minutes, of 1.0% by weight or more.

The temporary fixing layer has (A) a shear adhering strength to a silicon wafer, after it is kept at 200° C. for 1 minute, of 0.25 kg/5×5 mm or more at the temperature, and a shear adhering strength to a silicon wafer, after it is kept at any temperature range of higher than 200° C. and 500° C. or lower for 3 minutes, of less than 0.25 kg/5×5 mm at the temperature, or has (B) a weight loss rate, after it is immersed in N-methyl-2-pyrrolidone at 50° C. for 60 seconds and dried at 150° C. for 30 minutes, of 1.0% by weight or more. In the case of (A), the temporary fixing layer is not peeled off even when it is exposed to a high temperature to some extent, and it is peeled off in a higher temperature region. As a result, the temporary fixing layer can be made not to be peeled off even when it is exposed to a high temperature to some extent after the substrate for transferring and the functional layer are bonded with the temporary fixing layer interposed therebetween until the temporary fixing layer is separated from the functional layer. On the other hand, the temporary fixing layer can be peeled off by heating it to a high temperature in a stage of separating the temporary fixing layer from the functional layer.

According to the configuration, the functional layer can be transferred to the final substrate without forming the second and third etching layers that are necessary in the previous method of transferring a functional layer using wet etching. As a result, the production efficiency can be improved.

Because the peeling off is performed by decreasing the shear adhering strength under heating, damage to the functional layer can be decreased as compared to peeling off using a laser.

In the case of (B), the temporary fixing layer has a weight loss rate, after it is immersed in N-methyl-2-pyrrolidone (NMP) at 50° C. for 60 seconds and dried at 150° C. for 30 minutes, of 1.0% by weight or more. Because the weight loss rate after it is immersed in N-methyl-2-pyrrolidone (NMP) at 50° C. for 60 seconds and dried at 150° C. for 30 minutes is 1% by weight or more, the temporary fixing layer begins to dissolve into N-methyl-2-pyrrolidone, and the weight is decreased enough. As a result, the temporary fixing layer can be easily peeled off by using N-methyl-2-pyrrolidone (NMP) in a stage of separating the temporary fixing layer from the functional layer. The weight loss rate of the temporary fixing layer can be controlled by the solubility of a raw material to NMP. That is, as a material having high solubility to NMP is selected for the raw material, the solubility of the temporary fixing layer obtained by using the raw material to NMP becomes high.

According to the configuration, the functional layer can be transferred to the final substrate without forming the second and third etching layers that are necessary in the previous method of transferring a functional layer using wet etching. As a result, the production efficiency can be improved.

Because the peeling off is performed by using a solvent (N-methyl-2-pyrrolidone (NMP)), damage to the functional layer can be decreased as compared to peeling off using a laser.

In the configuration, the temporary fixing layer preferably has a dynamic hardness of 0.01 or more and 10 or less. When the temporary fixing layer has a dynamic hardness of 10 or less, followability of the functional layer to unevenness becomes good. On the other hand, when the temporary fixing layer has a dynamic hardness of 0.01 or more, an effect is obtained of functional layer shift control (suppression of positional shift due to a shape change of the temporary fixing layer when the functional layer is bonded to the final substrate).

In the configuration, the temporary fixing layer preferably has a weight loss rate, after it is immersed in a 3% aqueous tetramethylammonium hydroxide solution for 5 minutes, of less than 1% by weight. When the temporary fixing layer has a weight loss rate, after it is immersed in a 3% aqueous tetramethylammonium hydroxide solution for 5 minutes, of less than 1% by weight, solvent resistance (especially, solvent resistance to aqueous tetramethylammonium hydroxide solution) can be improved because the amount of the temporary fixing layer that is dissolved into the 3% aqueous tetramethylammonium hydroxide solution is small.

In the configuration, the temporary fixing layer preferably has a constituent unit derived from a diamine having an ether structure, and the constituent unit derived from a diamine having an ether structure preferably has a glycol skeleton or a glycol skeleton derived from a diamine having alkylene glycol. In the case where the temporary fixing layer has a constituent unit derived from a diamine having an ether structure, when the temporary fixing layer is heated to a high temperature such as 200° C. or higher, the shear adhering strength can be decreased. According to the phenomenon, the present inventors surmise that the shear adhering strength decreases because of detachment of the ether structure from the resin constituting the temporary fixing layer when it is heated to a high temperature. When the constituent unit derived from a diamine having an ether structure has a glycol skeleton or a glycol skeleton derived from a diamine having alkylene glycol, a good peeling property is exhibited by heating the temporary fixing layer to a high temperature such as 200° C. or higher.

Whether or not the temporary fixing layer has a diamine having a glycol skeleton can be confirmed by whether or not an FT-IR spectrum of the temporary fixing layer has an absorption peak at 2700 cm⁻¹ to 3000 cm⁻¹. That is, when the spectrum has an absorption peak at 2700 cm⁻¹ to 3000 cm⁻¹, the temporary fixing layer is determined to have a diamine having a glycol skeleton.

Especially, whether or not the temporary fixing layer has a diamine having a glycol skeleton derived from a diamine having alkylene glycol can be confirmed by whether or not an FT-IR spectrum of the temporary fixing layer has an absorption peak at 2700 cm⁻¹ to 3000 cm⁻¹.

In the configuration, the temporary fixing layer preferably includes, as a constituent material, a polyimide resin obtained by imidizing polyamic acid that is obtained by reacting acid anhydride, a diamine having an ether structure, and a diamine that does not have an ether structure, and the compounding ratio of the diamine having an ether structure to the diamine that does not have an ether structure is preferably in a range of 100:0 to 10:90 by mole ratio at the time of reacting the acid anhydride, the diamine having an ether structure, and the diamine that does not have an ether structure. When the compounding ratio of the diamine having an ether structure to the diamine that does not have an ether structure is in a range of 100:0 to 10:90 by mole ratio at the time of reacting the acid anhydride, the diamine having an ether structure, and the diamine that does not have an ether structure, a thermal peeling property at a high temperature is more excellent.

In the configuration, the diamine having an ether structure preferably has a molecular weight in a range of 200 to 5,000. When the diamine having an ether structure has a molecular weight in a range of 200 to 5,000, a temporary fixing layer can be easily obtained having high adhering strength at a low temperature and a peeling property at a high temperature. The molecular weight of the diamine having an ether structure is measured by GPC (gel permeation chromatography), and it is a value (weight average molecular weight) calculated in terms of polystyrene.

In the configuration, the substrate for forming a functional layer is preferably GaAs, GaP, sapphire, or SiC, and the functional layer is preferably a light-emitting layer. When the substrate for forming a functional layer is GaAs, GaP, sapphire, or SiC, and the functional layer is a light-emitting layer, higher heat dissipation can be obtained in the case where the final substrate is a high thermal conductive type.

### BRIEF DESCRIPTION OF THE DRAWINGS

FIG. 1 is a cross-sectional schematic diagram for illustrating a method of manufacturing a semiconductor element according to the present embodiment;

FIG. 2 is a cross-sectional schematic diagram for illustrating the method of manufacturing a semiconductor element according to the present embodiment;

FIG. 3 is a cross-sectional schematic diagram for illustrating the method of manufacturing a semiconductor element according to the present embodiment;

FIG. 4 is a cross-sectional schematic diagram for illustrating the method of manufacturing a semiconductor element according to the present embodiment;

FIG. 5 is a cross-sectional schematic diagram for illustrating the method of manufacturing a semiconductor element according to the present embodiment;

FIG. 6 is a cross-sectional schematic diagram for illustrating a method of manufacturing a semiconductor element according to another embodiment;

FIG. 7 is a cross-sectional schematic diagram for illustrating a previous method of transferring a substrate;

FIG. 8 is a cross-sectional schematic diagram for illustrating the previous method of transferring a substrate;

FIG. 9 is a cross-sectional schematic diagram for illustrating the previous method of transferring a substrate;

FIG. 10 is a cross-sectional schematic diagram for illustrating the previous method of transferring a substrate; and

FIG. 11 is a cross-sectional schematic diagram for illustrating the previous method of transferring a substrate.

### DESCRIPTION OF THE REFERENCE NUMERALS

10 Substrate for Forming Functional Layer

12 First Etching Layer

14 Functional Layer

20 Substrate for Transferring

24 Temporary Fixing Layer

30 Final Substrate

32 Reflection Layer

### DETAILED DESCRIPTION OF PREFERRED EMBODIMENTS

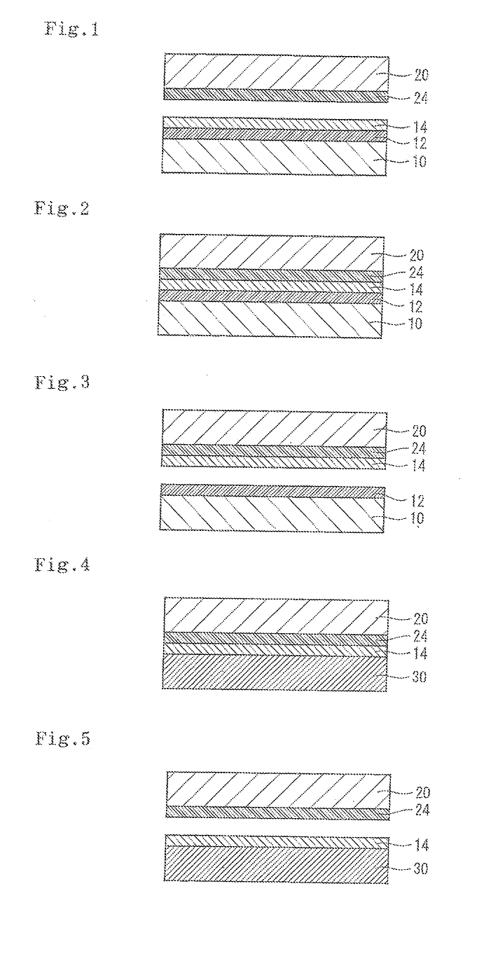

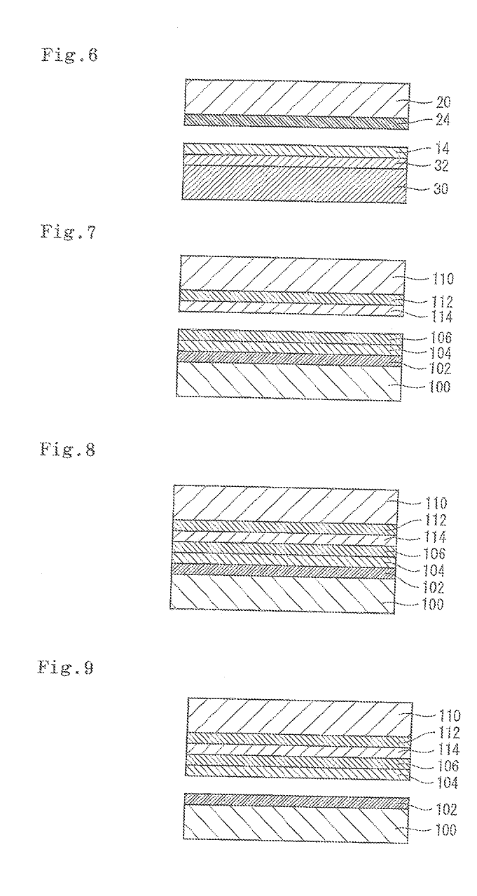

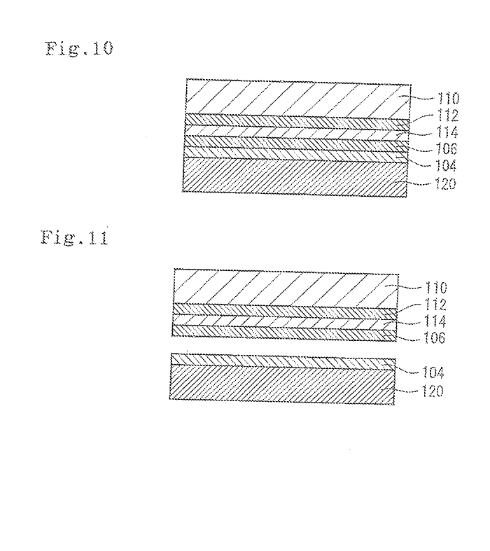

The embodiments of the present invention will be described with reference to the drawings. However, the present invention is not limited to these examples. FIGS. 1 to 5 are cross-sectional schematic diagrams for illustrating a method of manufacturing a semiconductor element according to the present embodiment. In the present specification, parts that are unnecessary for the description are not given in the drawings, and some parts are shown by enlargement, reduction or the like to make the description easy.

### [Method of Manufacturing Semiconductor Element]

The method of manufacturing a semiconductor element according to the present embodiment includes at least the steps of:
bonding a substrate 20 for transferring and a functional layer 14 that is formed on a substrate 10 for forming a functional layer with a temporary fixing layer 24 interposed therebetween,
removing the substrate 10 for forming a functional layer to expose the functional layer 14,
bonding a final substrate 30 to the exposed functional layer 14, and separating the temporary fixing layer 24 and the substrate 20 for transferring from the functional layer 14, wherein
the temporary fixing layer 24 has (A) a shear adhering strength to a silicon wafer, after it is kept at 200° C. for 1 minute, of 0.25 kg/5×5 mm or more at the temperature, and a shear adhering strength to a silicon wafer, after it is kept at any temperature range of higher than 200° C. and 500° C. or lower for 3 minutes, of less than 0.25 kg/5×5 mm at the temperature, or has (B) a weight loss rate, after it is immersed in N-methyl-2-pyrrolidone at 50° C. for 60 seconds and dried at 150° C. for 30 minutes, of 1.0% by weight or more. The method of manufacturing a semiconductor element according to the present embodiment will be described in detail below.

As shown in FIG. 1, a first etching layer 12 is formed first on a substrate 10 for forming a functional layer. Examples of the substrate 10 for forming a functional layer can include GaAs, GaP, sapphire, and SiC substrates. When these substrates are used, a functional layer 14 can be formed on the substrate with a liquid phase epitaxial growth method or a metal organic chemical vapor deposition method. An example of the first etching layer 12 can include a layer in which lattice-shaped silicon oxide is formed in a nitride layer as described in JP-A-2009-99989. The detail of the first etching layer 12 will be described later. However, it is a layer that is dissolved by an etchant when the substrate 10 for forming a functional layer is separated from the functional layer 14. Especially, when the first etching layer 12 is a layer in which lattice-shaped silicon oxide is formed in a nitride layer, silicon oxide is removed by etching, and a hollow passage is introduced into the nitride layer to separate the substrate 10 for forming a functional layer from the functional layer 14.

Then, the functional layer 14 is formed on the first etching layer 12 with a liquid phase epitaxial growth method or a metal organic chemical vapor deposition method. The functional layer 14 is a layer that exhibits various functions as a semiconductor element, and a previously known functional layer can be adopted. Examples of the functional layer 14 can include a light-emitting layer that emits light such as an LED (Light Emitting Diode) and a layer having a function of photoelectric conversion such as an image sensor or a solar cell.

On the other hand, a substrate 20 for transferring is prepared, and a temporary fixing layer 24 is formed on the substrate 20 for transferring.

The substrate 20 for transferring is not especially limited. However, a substrate having excellent heat resistance is preferable, and examples thereof can include substrates that are formed from materials such as silicon and glass.

Here, the temporary fixing layer 24 will be described in detail.

The temporary fixing layer 24 has (A) a shear adhering strength to a silicon wafer, after it is kept at 200° C. for 1 minute, of preferably 0.25 kg/5×5 mm or more, more preferably 0.30 kg/5×5 mm or more, and further preferably 0.50 kg/5×5 mm or more at the temperature. Further, the temporary fixing layer 24 has a shear adhering strength to a silicon wafer, after it is kept at any temperature range of higher than 200° C. and 500° C. or lower for 3 minutes, of preferably less than 0.25 kg/5×5 mm, more preferably less than 0.10 kg/5×5 mm, and further preferably less than 0.05 kg/5×5 mm at the temperature. Because the temporary fixing layer 24 has a shear adhering strength to a silicon wafer, after it is kept at 200° C. for 1 minute, of 0.25 kg/5×5 mm or more at the temperature, and a shear adhering strength to a silicon wafer, after it is kept at temperature range of higher than 200° C. and 500° C. or lower for 3 minutes, of less than 0.25 kg/5×5 mm at the temperature, the temporary fixing layer 24 is not peeled off even when it is exposed to a high temperature to some extent, and it is peeled off in a higher temperature region. As a result, the temporary fixing layer 24 can be made not to be peeled off even when it is exposed to a high temperature to some extent after the substrate 20 for transferring and the functional layer 14 are bonded (temporarily fixed) with the temporary fixing layer 24 interposed therebetween until the temporary fixing layer 24 is separated from the functional layer 14. On the other hand, the temporary fixing layer 24 can be peeled off by heating it to a high temperature in a stage of separating it from the functional layer 14. The shear adhering strength of the temporary fixing layer 24 can be controlled by, for example, a number of functional groups contained in the temporary fixing layer 24.

The temperature at which the temporary fixing layer 24 has a shear adhering strength to a silicon wafer of less than 0.25 kg/5×5 mm (preferably less than 0.10 kg/5×5 mm, and more preferably less than 0.05 kg/5×5 mm) is not especially limited as long as it is any temperature higher than 200° C. and 500° C. or lower. However, it is preferably higher than 220° C. and 480° C. or lower, and more preferably higher than 240° C. and 450° C. or lower.

Even when the temperature is 200° C. or lower, the temporary fixing layer 24 may have a shear adhering strength to a silicon wafer of less than 0.25 kg/5×5 mm if it is kept at that temperature for a long time. Even when the temporary fixing layer 24 is kept at a temperature higher than 200° C., the shear adhering strength to a silicon wafer may not be less than 0.25 kg/5×5mm if it is kept at that temperature for a short time.

“A shear adhering strength to a silicon wafer, after the temporary fixing layer is kept at any temperature range of higher than 200° C. and 500° C. or lower for 3 minutes, of less than 0.25 kg/5×5 mm at the temperature” is an indication for evaluating the peeling property at a high temperature, and it does not mean that the shear adhering strength to a silicon wafer immediately becomes less than 0.25 kg/5×5 mm when the temperature becomes “any temperature range of higher than 200° C. and 500° C. or lower”. Nor does it mean that the peeling property is not exhibited when the temperature does not become “any temperature range of higher than 200° C. and 500° C. or lower”.

The temporary fixing layer 24 has (B) a weight loss rate, after it is immersed in N-methyl-2-pyrrolidone (NMP) at 50° C. for 60 seconds and dried at 150° C. for 30 minutes, of preferably 1.0% by weight or more, more preferably 1.1% by weight or more, and further preferably 1.2% by weight or more. The larger the weight loss rate is, the more preferable it is, and for example, it is 50% by weight or less, or 40% by weight or less. When the temporary fixing layer 24 has a weight loss rate, after it is immersed in N-methyl-2-pyrrolidone (NMP) at 50° C. for 60 seconds and dried at 150° C. for 30 minutes, of 1.0% by weight or more, the temporary fixing layer 24 begins to dissolve into N-methyl-2-pyrrolidone, and the weight is decreased enough. As a result, the temporary fixing layer 24 can be easily peeled off by using N-methyl-2-pyrrolidone. The weight loss rate of the temporary fixing layer 24 can be controlled by the solubility of a raw material to NMP. That is, as a material having high solubility to NMP is selected for the raw material, the solubility of the temporary fixing layer 24 obtained by using the raw material to NMP becomes high.

The temporary fixing layer 24 has a dynamic hardness of preferably 10 or less, more preferably 9 or less, and further preferably 8 or less. The smaller the dynamic hardness, the more preferable it is, and for example, it is 0.01 or more. When the dynamic hardness is 10 or less, the adhering strength of the temporary fixing layer 24 to the substrate 20 for transferring and the functional layer 14 can be made sufficient. When the dynamic hardness is 10 or less, followability of the functional layer 14 to unevenness becomes good. On the other hand, when the temporary fixing layer 24 has a dynamic hardness of 0.01 or more, an effect can be obtained of a functional layer shift control (suppression of positional shift due to a shape change of the temporary fixing layer 24 when the functional layer 14 is bonded to the final substrate 30).

The temporary fixing layer 24 has a weight loss rate, after it is immersed in a 3% aqueous tetramethylammonium hydroxide solution for 5 minutes, of preferably less than 1% by weight, more preferably less than 0.9% by weight, and further preferably less than 0.8% by weight. The smaller the weight loss rate is, the more preferable it is, and for example, it is 0% by weight or more, or 0.001% by weight or more. When the temporary fixing layer 24 has a weight loss rate, after it is immersed in a 3% aqueous tetramethylammonium hydroxide solution for 5 minutes, of less than 1% by weight, solvent resistance (especially, solvent resistance to aqueous tetramethylammonium hydroxide solution) can be improved because the amount of the temporary fixing layer that is dissolved into the 3% aqueous tetramethylammonium hydroxide solution is small. The weight loss rate of the temporary fixing layer 24 can be controlled, for example, by the composition (solubility of diamine to aqueous tetramethylammonium hydroxide solution) of a diamine to be used.

The increase in the amount of particles having a size of 0.2 μm or more on a silicon wafer, at the time when the temporary fixing layer 24 is peeled off after it is bonded to the silicon wafer, is preferably less than 10,000 particles/6 inch wafer, more preferably less than 9,000 particles/6 inch wafer, and further preferably less than 8,000 particles/6 inch wafer, based on the amount of particles before the temporary fixing layer is bonded to the silicon wafer. The increase in the amount of particles is especially preferably less than 1,000 particles/6 inch wafer, less than 900 particles/6 inch wafer, or less than 800 particles/6 inch wafer, based on the amount of particles before the temporary fixing layer is bonded to the silicon wafer. When the increase in the amount of particles having a size of 0.2 μm or more on a silicon wafer, at the time when the temporary fixing layer 24 is peeled off after it is bonded to the silicon wafer, is less than 10,000 particles/6 inch wafer based on the amount of particles before the temporary fixing layer is bonded to the silicon wafer, adhesive residue after peeling off can be suppressed.

When the temporary fixing layer 24 has (A) a shear adhering strength to a silicon wafer, after it is kept at 200° C. for 1 minute, of 0.25 kg/5×5 mm or more at the temperature, and a shear adhering strength to a silicon wafer, after it is kept at any temperature range of higher than 200° C. and 500° C. or lower for 3 minutes, of less than 0.25 kg/5×5 mm at the temperature, or has (B) a weight loss rate, after it is immersed in N-methyl-2-pyrrolidone at 50° C. for 60 seconds and dried at 150° C. for 30 minutes, of 1.0% by weight or more, the material that forms the temporary fixing layer 24 is not especially limited. However, examples thereof can include a polyimide resin, a silicone resin, an acrylic resin, a fluororesin, an epoxy resin, a urethane resin, and a rubber resin.

The polyimide resin can be generally obtained by imidizing (dehydration synthesis) polyamic acid that is a precursor of the polyimide resin. Examples of methods of imidizing polyamic acid include previously known methods such as heating imidization, azeotropic dehydration, and chemical imidization. Among these, heating imidization is preferable. When the heating imidization is adopted, the heating process is preferably performed under an inert atmosphere such as a nitrogen atmosphere or in vacuum in order to prevent the polyimide resin from deterioration due to oxidation.

The polyamic acid can be obtained by charging acid anhydride and a diamine so that the acid anhydride and the diamine have substantially equal mole ratio in a solvent appropriately selected, and they are allowed to react with each other.

The polyimide resin preferably has a constituent unit derived from a diamine having an ether structure. The diamine having an ether structure is not especially limited as long as it has an ether structure and is a compound having at least two terminals having an amine structure. Among the diamines having an ether structure, a diamine having a glycol skeleton is preferable. In the case where the polyimide resin has a constituent unit derived from a diamine having an ether structure, especially a constituent unit derived from a diamine having a glycol skeleton, the shear adhering strength can be decreased when the temporary fixing layer 24 is heated. According to the phenomenon, the present inventors surmise that the shear adhering strength decreases because of detachment of the ether structure or the glycol skeleton from the resin constituting the temporary fixing layer 24 when it is heated to a high temperature.

The detachment of the ether structure or the glycol skeleton from the resin constituting the temporary fixing layer 24 can be confirmed from a decrease of the spectrum at 2,800 cm⁻¹ to 3,000 cm⁻¹ when the FT-IR (Fourier transform infrared spectroscopy) spectra before and after it is heated at 300° C. for 30 minutes are compared.

Examples of the diamine having a glycol skeleton can include diamines having alkylene glycol such as a diamine having a polypropylene glycol structure and having one amino group on each of the terminals, a diamine having a polyethylene glycol structure and having one amino group on each of the terminals, and a diamine having a polytetramethylene glycol structure and having one amino group on each of the terminals. Further, there can be exemplified a diamine having a plurality of these glycol structures and having one amino group on each of the terminals.

The diamine having an ether structure preferably has a molecular weight in a range of 200 to 5,000, and more preferably 230 to 4,500. When the diamine having an ether structure has a molecular weight in a range of 200 to 5,000, the temporary fixing layer 24 can be easily obtained having high adhering strength at a low temperature and a peeling property at a high temperature.

A diamine that does not have an ether structure can be used together with the diamine having an ether structure for forming the polyimide resin. Examples of the diamine that does not have an ether structure can include an aliphatic diamine and an aromatic diamine. The diamine that does not have an ether structure may be used together with the diamine having an ether structure to control adhesive force with the functional layer or the substrate for transferring. The compounding ratio of the diamine having an ether structure to the diamine that does not have an ether structure is preferably in a range of 100:0 to 10:90 by mole ratio, more preferably 100:0 to 20:80, and further preferably 99:1 to 30:70. When the compounding ratio of the diamine having an ether structure to the diamine that does not have an ether structure is in a range of 100:0 to 10:90 by mole ratio, a thermal peeling property at a high temperature is more excellent.

Examples of the aliphatic diamine include ethylene diamine, hexamethylene diamine, 1,8-diaminooctane, 1,10-diaminodecane, 1,12-diaminododecane, 4,9-dioxa-1,12-diaminododecane, and 1,3-bis(3-aminopropyl)-1,1,3,3-tetramethyldisiloxane(α,ω-bisaminopropyltetramethyldisiloxane). The aliphatic diamine has a molecular weight of normally 50 to 1,000,000, and preferably 100 to 30,000.

Examples of the aromatic diamine include 4,4′-diaminodiphenylether, 3,4′-diaminodiphenylether, 3,3′-diaminodipheylether, m-phenylenediamine, p-phenylenediamine, 4,4′-diaminodiphenylpropane, 3,3′-diaminodiphenylmethane, 4,4′-diaminodiphenylsulfide, 3,3′-diaminodiphenylsulfide, 4,4′-diaminodiphenylsulfone, 3,3′-diaminodiphenylsulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone. The aromatic diamine has a molecular weight of normally 50 to 1,000, and preferably 100 to 500. The molecular weight in the present specification is measured by GPC (gel permeation chromatography), and it is a value (weight average molecular weight) calculated in terms of polystyrene.

Examples of the acid anhydride include 3,3′,4,4′-biphenyl tetracarboxylicaciddianhydride, 2,2′,3,3′-biphenyl tetracarboxylic acid dianhydride, 3,3′,4,4′-benzophenone tetracarboxylic acid dianhydride, 2,2′,3,3′-benzophenone tetracarboxylic acid dianhydride, 4,4′-oxydiphthalic acid dianhydride, 2,2-bis(2,3-dicarboxyphenyl)hexafluoropropane dianhydride, 2,2-bis(3,4-dicarboxyphenyl)hexafluoropropane dianhydride (6FDA), bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic acid dianhydride, and ethylene glycol bistrimellitic acid dianhydride. These may be used alone or two types or more may be used together.

Examples of the solvent at the time of reaction of the acid anhydride with the diamine include N,N-dimethylacetoamide, N-methyl-2-pyrrolidone, N,N-dimethylformamide, and cyclopentanone. These may be used alone or a plurality of them may be mixed and used. In addition, a nonpolar solvent such as toluene or xylene may be appropriately mixed and used in order to adjust the solubility of the raw material or the resin.

For example, the temporary fixing layer 24 can be produced as follows. First, a solution containing the polyamic acid is prepared. Next, the solution is applied onto a substrate to form a coating film having a prescribed thickness, and then the coating film is dried under a prescribed condition. Examples of the substrate that can be used include metal foils such as SUS 304, a 6-4 alloy, an aluminum foil, a copper foil, and a Ni foil; polyethylene terephthalate (PET); polyethylene; polypropylene; and a plastic film and paper whose surfaces are coated with a peeling agent such as a fluorine-based peeling agent or a long chain alkylacrylate-based peeling agent. Examples of the application method include, but are not especially limited to, roll coating, screen coating, gravure coating, and spin coating. For the drying condition, for example, the drying temperature is in a range of 50° C. to 150° C. and a drying time is in a range of 3 minutes to 30 minutes. Then, the film is thermally cured (imidization) in nitrogen or in vacuum at 150° C. to 400° C. for 30 minutes to 240 minutes. Thus, the temporary fixing layer 24 according to the present embodiment can be obtained. The sheet-shaped temporary fixing layer 24 obtained in such a manner can be used by bonding it to the substrate 20 for transferring. A previously known method can be adopted for the bonding method, and examples thereof can include press and roll lamination.

Further, the liquid solution can be directly applied onto the substrate 20 for transferring to form the temporary fixing layer 24. Examples of the application method include, but are not especially limited to, roll coating, screen coating, gravure coating, and spin coating. For the drying condition, for example, the drying temperature is in a range of 50° C. to 150° C. and a drying time is in a range of 3 minutes to 30 minutes. Then, the film is thermally cured (imidization) in nitrogen or in vacuum at 150° C. to 400° C. for 30 minutes to 240 minutes. Thus, the temporary fixing layer 24 according to the present embodiment can be obtained.

Next, as shown in FIG. 2, the substrate 20 for transferring and the function layer 14 that is formed on the substrate 10 for forming a functional layer are bonded together with the temporary fixing layer 24 interposed therebetween.

Then, the first etching layer 12 is etched using an etchant for etching the first etching layer 12. Thus, the substrate 10 for forming a functional layer is removed, and the functional layer 14 is exposed (see FIG. 3).

Then, the final substrate 30 is bonded to the exposed functional layer 14 (see FIG. 4).

Next, the temporary fixing layer 24 and the substrate 20 for transferring are separated from the functional layer 14 (FIG. 5). Examples of the separation method include (a) separation by heating the temporary fixing layer to a high temperature and (b) separation by immersing the temporary fixing layer in N-methyl-2-pyrrolidone.

In the case of (a), the temporary fixing layer is heated to a high temperature, and the shear adhering strength of the temporary fixing layer 24 is decreased to separate the temporary fixing layer 24 and the substrate 20 for transferring from the functional layer 14. As the condition of heating to a high temperature, the temperature can be appropriately set within a range in which the shear adhering strength of the temporary fixing layer 24 can be decreased and the temporary fixing layer 24 and the substrate 20 for transferring can be separated from the functional layer 14. However, examples of the lower limit include 180° C., 200° C., and 250° C. Examples of the upper limit include 300° C., 350° C., and 400° C. The time to maintain the temperature condition in the step of heating the temporary fixing layer to a high temperature depends on the temperature. However, it is preferably 0.05 minutes to 120 minutes and more preferably 0.1 minutes to 30 minutes.

In the case of (b), the temporary fixing layer is immersed in N-methyl-2-pyrrolidone at −10° C. to 100° C. for 1 second to 600 seconds, and the shear adhering strength of the temporary fixing layer 24 is decreased to separate the temporary fixing layer 24 and the substrate 20 for transferring from the functional layer 14.

As described above, the functional layer 14 can be transferred from the substrate 10 for forming a functional layer to the final substrate 30 to obtain a semiconductor element in which the functional layer 14 is layered on the final substrate 30.

The final substrate 30 is not especially limited. However, a high thermal conductive substrate that is excellent in thermal conductivity such as an alumina substrate is preferable. When the final substrate 30 is a high thermal conductive substrate and the functional layer 14 is a light-emitting layer, a light-emitting device having an excellent light-emitting efficiency can be obtained.

According to the method of manufacturing a semiconductor element according to the present embodiment, the functional layer can be transferred to the final substrate without forming the second and third etching layers that are necessary in the previous method of transferring a functional layer using wet etching. As a result, the production efficiency can be improved. Because the peeling off is performed by decreasing the shear adhering strength under heating, damage to the functional layer can be decreased as compared to peeling off using a laser.

In the embodiment, the case is described where the temporary fixing layer 24 satisfies (A) and (B). That is, the case is described where the temporary fixing layer 24 has (A) a shear adhering strength to a silicon wafer, after it is kept at 200° C. for 1 minute, of 0.25 kg/5×5 mm or more at the temperature, and a shear adhering strength to a silicon wafer, after it is kept at any temperature range of higher than 200° C. and 500° C. or lower for 3 minutes, of less than 0.25 kg/5×5 mm at the temperature, and has (B) a weight loss rate, after it is immersed in N-methyl-2-pyrrolidone at 50° C. for 60 seconds and dried at 150° C. for 30 minutes, of 1.0% by weight or more.

However, the temporary fixing layer in the present invention should satisfy at least one of (A) and (B).

FIG. 6 is a cross-sectional schematic diagram for illustrating a method of manufacturing a semiconductor element according to another embodiment.

In the above embodiment, the case is described where the functional layer 14 is directly bonded onto the final substrate 30. However, the present invention is not limited to this embodiment. As shown in FIG. 6, a reflection layer 32 may be formed on the final substrate 30 to bond the functional layer 14 to the final substrate 30 with the reflection layer 32 interposed therebetween. When the reflection layer 32 is provided, the light-emitting efficiency of light emitted from the functional layer 14 as a light-emitting layer can be further improved.

### EXAMPLES

The preferred Examples of the present invention will be illustratively described in detail below. However, the gist of the present invention is not limited only to the material, the compounding amount, or the like described in the Examples as long as there is no restrictive description in particular.

### Example 1

In a nitrogen stream, 8.05 g of polyether diamine (D-4000 manufactured by Huntsman International LLC., molecular weight: 4023.5) and 8.78 g of 4,4′-diaminodiphenylether (DDE, molecular weight: 200.2), and 10.0 g of pyromellitic acid dianhydride (PMDA, molecular weight: 218.1) were mixed in 140.85 g of N,N-dimethylacetoamide (DMAc) and reacted at 70° C. to obtain a polyamic acid solution A. After cooling to room temperature (23° C.), the polyamic acid solution A was applied onto a mirror surface of an 8 inch silicon wafer with a spin coater, and the resultant was dried at 90° C. for 20 minutes to obtain a substrate A for transferring with polyamic acid. The substrate A for transferring with polyamic acid was subjected to heat treatment at 300° C. under a nitrogen atmosphere for 2 hours, and a polyimide film (a temporary fixing layer) having a thickness of 30 μm was formed to obtain a substrate A for transferring with a temporary fixing layer.

### Example 2

In a nitrogen stream, 10.21 g of polyether diamine (D-2000 manufactured by Huntsman International LLC., molecular weight: 1990.8) and 8.15 g of 4,4′-diaminodiphenylether (DDE, molecular weight: 200.2), and 10.0 g of pyromellitic acid dianhydride (PMDA, molecular weight: 218.1) were mixed in 138.48 g of N,N-dimethylacetoamide (DMAc) and reacted at 70° C. to obtain a polyamic acid solution B. After cooling to room temperature (23° C.), the polyamic acid solution B was applied onto an SUS foil (thickness 38 μm) so that the thickness after drying became 50 μm, and the resultant was dried at 90° C. for 20 minutes to obtain a substrate B for transferring with polyamic acid. The substrate B for transferring with polyamic acid was subjected to heat treatment at 300° C. under a nitrogen atmosphere for 2 hours, and a polyimide film (a temporary fixing layer) having a thickness of 50 μm was formed to obtain a substrate B for transferring with a temporary fixing layer.

### Comparative Example 1

In a nitrogen stream, 9.18 g of 4,4′-diaminodiphenylether (DDE, molecular weight: 200.2), and 10.00 g of pyromellitic acid dianhydride (PMDA, molecular weight: 218.1) were mixed in 364.42 g of N,N-dimethylacetoamide (DMAc) and reacted at 70° C. to obtain a polyamic acid solution C. After cooling to room temperature (23° C.), the polyamic acid solution C was applied onto a mirror surface of an 8 inch silicon wafer with a spin coater, and the resultant was dried at 90° C. for 20 minutes to obtain a substrate C for transferring with polyamic acid. The substrate C for transferring with polyamic acid was subjected to heat treatment at 300° C. under a nitrogen atmosphere for 2 hours, and a polyimide film (a temporary fixing layer) having a thickness of 30 μm was formed to obtain a substrate C for transferring with a temporary fixing layer.

### Measurement of Shear Adhering Strength to Silicon Wafer

A silicon wafer chip of 5 mm square (thickness 500 μm) was placed on the temporary fixing layer that was formed on the substrate for transferring, it was laminated under conditions of 60° C. and 10 mm/second, and the shear adhering strength of the temporary fixing layer and silicon wafer chip was measured using a shear tester (Dage 4000 manufactured by Dage Holdings Ltd.) Two conditions of the shear testing were as follows. The results are shown in Table 1. The measurement was not performed for Comparative Example 1 because the sample did not adhere to a silicon wafer chip.

<Condition 1 of Shear Testing>
Stage temperature: 200° C.
Time from the sample was held on the stage until the measurement of the shear adhering strength was started: 1 minute
Measurement speed: 500 μm/second
Measurement gap: 100 μm

<Condition 2 of Shear Testing>
Stage temperature: 260° C.
Time from the sample was held on the stage until the measurement of the shear adhering strength was started: 3 minutes
Measurement speed: 500 μm/second
Measurement gap: 100 μm
   (Measurement of Weight Loss Rate when Being Immersed in Aqueous Tetramethylammonium Hydroxide Solution)

First, the substrate for transferring was peeled off from the substrate for transferring with a temporary fixing layer of each of the Examples and Comparative Example. Next, a 100 mm square piece of the peeled temporary fixing layer was cut out, and its weight was measured. Then, it was immersed in a 3% aqueous tetramethylammonium hydroxide solution (TMAH) at 23° C. for 5 minutes. It was thoroughly washed with water, and dried at 150° C. for 30 minutes. After that, the weight was measured and defined as weight after immersion.

The weight loss rate was obtained according to the following equation. The results are shown in Table 1. The measurement was not performed for Comparative Example 1.

(Weight loss rate (% by weight))=[1−((Weight after immersion)/(Weight before immersion))]×100

(Measurement of Weight Loss Rate when Being Immersed in N-methyl-2-pyrrolidone)

First, the substrate for transferring was peeled off from the substrate for transferring with a temporary fixing layer of each of the Examples and the Comparative Example. Next, a 100 mm square piece of the peeled temporary fixing layer was cut out, and its weight was measured. Then, it was immersed in N-methyl-2-pyrrolidone (NMP) at 50° C. for 60 seconds. It was thoroughly washed with water, and dried at 150° C. for 30 minutes. After that, the weight was measured and defined as weight after immersion.

The weight loss rate was obtained according to the following equation. The results are shown in Table 1. The measurement was not performed for Comparative Example 1.

(Weight loss rate (% by weight))=[1−((Weight after immersion)/(Weight before immersion))−1]×100

### (Evaluation of Adhesive Residue)

First, the substrate for transferring was peeled off from the substrate for transferring with a temporary fixing layer of each of the Examples and Comparative Example. Next, the temporary fixing layer of each of the Examples and Comparative Example was processed to have a diameter of 6 inches, and laminated onto a wafer having a diameter of 8 inch under conditions of 60° C. and 10 mm/second. After that, it was allowed to leave for 1 minute and peeled off. The number of particles having a size of 0.2 μm or more on a surface of the wafer having a diameter of 8 inch was measured using a particle counter (SFS 6200 manufactured by KLA-Tencor Inc.). The evaluation was performed by marking ◯ when the increase in the amount of particles after peeling off was less than 1,000 particles/6 inch wafer, and marking x when it was 1,000 particles/6 inch wafer or more, as compared to before lamination. The results are shown in Table 1. The measurement was not performed for Comparative Example 1 because the sample did not adhere to the wafer.

### (Peeling Off Temperature)

A piece of 30 mm square was made from the temporary fixing layer of each of the Examples and Comparative Example, and a glass (thickness: 2 mm) of 10 mm square was bonded onto the piece of the temporary fixing layer using a laminator. Using this sample, the temperature at which the glass was peeled off from the temporary fixing layer was measured by heating under conditions of a rising temperature speed of 4° C./minute and a measurement temperature of 20 to 350° C. with a high temperature observation machine (product name: SK-5000) manufactured by Sanyo Seiko Co., Ltd. The results are shown in Table 1. The measurement was not performed for Comparative Example 1 because the sample did not adhere to the glass.

### (Gas Visual Temperature)

A piece of 30 mm square was made from the temporary fixing layer of each of the Examples and Comparative Example, and a glass (thickness: 2 mm) of 10 mm square was bonded onto the piece of the temporary fixing layer using a laminator. Using this sample, the temperature at which white smoke was generated was measured by heating under conditions of a rising temperature speed of 4° C./minute and a measurement temperature of 20 to 350° C. with a high temperature observation machine (product name: SK-5000) manufactured by Sanyo Seiko Co., Ltd. The results are shown in Table 1. The measurement was not performed for Comparative Example 1 because the sample did not adhere to the glass.

### (Dynamic Hardness)

The dynamic hardness of the temporary fixing layer of each of the Examples was measured by performing a load-unload testing at a load of 0.5 mN using a hardness tester (product name: DUH-210) manufactured by SHIMADZU CORPORATION and an indenter (product name: Triangular 115, manufactured by SHIMADZU CORPORATION). The results are shown in Table 1. The measurement was not performed for Comparative Example 1.

TABLE 1

| | | | Comparative |
|---|---|---|---|
| | Example 1 | Example 2 | Example 1 |
| Shear Adhering Strength at | 1.20 | 1.01 | — |
| 200° C. (kg/5 × 5 mm) | | | |
| Shear Adhering Strength at | 0.21 | 0.13 | — |
| 260° C. (kg/5 × 5 mm) | | | |
| TMAH Weight Loss Rate (% by | 0.65 | 0.32 | — |
| weight) | | | |
| NMP Weight Loss Rate (% by | 1.10 | 1.22 | — |
| weight) | | | |
| Evaluation of Adhesive Residue | ◯ | ◯ | — |
| Peeling off Temperature (° C.) | 208 | 239 | — |
| Gas Visual Temperature (° C.) | 243 | 238 | — |
| Dynamic Hardness | 3.9 | 3.9 | — |

What is claimed is:

1. A method of manufacturing a semiconductor element comprising the steps of:
bonding a substrate for transferring and a functional layer that is formed on a substrate for forming a functional layer with a temporary fixing layer interposed therebetween;
removing the substrate for forming a functional layer to expose the functional layer;
bonding a final substrate to the exposed functional layer; and
separating the temporary fixing layer and the substrate for transferring from the functional layer, wherein
the temporary fixing layer has (A) a shear adhering strength to a silicon wafer, after it is kept at 200° C. for 1 minute, of 0.25 kg/5×5 mm or more at 200° C., and a shear adhering strength to a silicon wafer, after it is kept at a temperature within a range of higher than 200° C. and 500° C. or lower for 3 minutes, of less than 0.25 kg/5×5 mm at the temperature within the range, or has (B) a weight loss rate, after it is immersed in N-methyl-2-pyrrolidone at 50° C. for 60 seconds and dried at 150° C. for 30 minutes, of 1.0% by weight or more.

2. The method of manufacturing a semiconductor element according to claim 1, wherein the temporary fixing layer has a dynamic hardness of 0.01 or more and 10 or less.

3. The method of manufacturing a semiconductor element according to claim 1, wherein the temporary fixing layer has a weight loss rate, after it is immersed in a 3% aqueous tetramethylammonium hydroxide solution for 5 minutes, of less than 1.0% by weight.

4. The method of manufacturing a semiconductor element according to claim 1, wherein
the temporary fixing layer has a constituent unit derived from a diamine having an ether structure, and
the constituent unit derived from a diamine having an ether structure has a glycol skeleton or a glycol skeleton derived from a diamine having alkylene glycol.

5. The method of manufacturing a semiconductor element according to claim 1, wherein the temporary fixing layer includes, as a constituent material, a polyimide resin obtained by imidizing polyamic acid that is obtained by reacting acid anhydride, a diamine having an ether structure, and a diamine that does not have an ether structure, and the compounding ratio of the diamine having an ether structure to the diamine that does not have an ether structure is 100:0 to 10:90 by mole ratio at a time of reacting acid anhydride, diamine having an ether structure, and the diamine that does not have an ether structure.

6. The method of manufacturing a semiconductor element according to claim 5, wherein the diamine having the ether structure has a molecular weight in a range of 200 to 5,000.

7. The method of manufacturing a semiconductor element according to claim 1, wherein the substrate for forming the functional layer is GaAs, GaP, sapphire, or SiC, and the functional layer is a light-emitting layer.
